(19) United States
(12) Patent Application Publication
(10) Pub. No.: US 2025/0226770 A1
(43) Pub. Date: Jul. 10, 2025

(54) Substrate Lift Pins and Substrate Supports and Process Chambers Incorporating Same

(71) Applicant: Applied Materials, Inc., Santa Clara, CA (US)

(72) Inventors: George KIM, Cupertino, CA (US); Joseph F. SOMMERS, San Jose, CA (US); Joseph Frederick BEHNKE, San Jose, CA (US)

(21) Appl. No.: 18/407,033

(22) Filed: Jan. 8, 2024

(51) Int. Cl. H02N 15/00

(52) U.S. Cl. CPC H02N 15/00

(57) ABSTRACT

Embodiments of substrate lift pins for use in process chambers are provided herein. In some embodiments, a substrate lift pin includes: an elongate tube having a top end and a bottom end; a magnetic insert disposed in the elongate tube proximate the bottom end; and a potting material disposed within the elongate tube and securing the magnetic insert within the elongate tube. A cap having a support surface configured to support a substrate can be disposed on the top end of the elongate tube. A rod can be disposed within the elongate tube, above the magnetic insert.

### FIELD

Embodiments of the present disclosure generally relate to substrate processing equipment, and more particularly, to lift pins for handling substrates within substrate processing chambers.

### BACKGROUND

In the processing of substrates, such as a semiconductor substrate or wafer, the substrate is typically held on a support surface of a substrate support in a processing chamber during processing. The processing chamber can include substrate lift pins that pass through the substrate support to selectively raise or lower the substrate off of or onto the support surface. In some substrate supports, the substrate lift pins extend completely through the substrate support and are moved relative to the substrate support surface (e.g., raised and lowered) at least in part by contacting a bottom surface of the substrate lift pin with a structural member disposed beneath the substrate lift pin. The inventors have observed that certain substrate lift pin designs tend to have premature failure-believed to be due to compromises in manufacturing of the structural member for raising and lowering the substrate lift pin—that leads to production stoppage and increased part replacement costs.

Accordingly, the inventors have provided herein embodiments of improved substrate lift pins and substrate supports and processing chambers incorporating same.

### SUMMARY

Embodiments of substrate lift pins for use in process chambers are provided herein. In some embodiments, a substrate lift pin includes: an elongate tube having a top end and a bottom end; a magnetic insert disposed in the elongate tube proximate the bottom end; and a potting material disposed within the elongate tube and securing the magnetic insert within the elongate tube. A cap having a support surface configured to support a substrate can be disposed on the top end of the elongate tube. A rod can be disposed within the elongate tube, above the magnetic insert. Any one or more of the elongate tube, the cap, and/or the rod can be made of a ceramic material, such as, for example, aluminum oxide. The potting material can be a ceramic-based potting material.

In some embodiments, a substrate support includes: a support plate having an upper surface and a plurality of through holes extending through the support plate; and a plurality of substrate lift pins each movably disposed in corresponding ones of the plurality of through holes. Each substrate lift pin can include: an elongate tube having a top end and a bottom end; a magnetic insert disposed in the elongate tube proximate the bottom end; and a potting material disposed within the elongate tube and securing the magnetic insert within the elongate tube. Each substrate lift pin can further be configured as described in any of the embodiments disclosed herein.

In some embodiments, a process chamber includes: a chamber body defining an interior volume therein; a substrate support disposed in the interior volume, the substrate support comprising a support plate having an upper surface and a plurality of through holes extending through the support plate; and a plurality of substrate lift pins each movably disposed in corresponding ones of the plurality of through holes. Each substrate lift pin can include: an elongate tube having a top end and a bottom end; a magnetic insert disposed in the elongate tube proximate the bottom end; and a potting material disposed within the elongate tube and securing the magnetic insert within the elongate tube. Each substrate lift pin can further be configured as described in any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a substrate lift pin in accordance with at least some embodiments of the present disclosure.

FIG. 2 depicts a schematic side view of a substrate lift pin in accordance with at least some embodiments of the present disclosure.

FIG. 3 depicts a schematic cross-sectional side view of a process chamber having a substrate support and substrate lift pins in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate lift pins and substrate supports and process chambers incorporating such lift pins are provided herein. The substrate lift pins provided herein generally have reduced defects and improved lifetime with reduced cost as compared to conventional lift pins.

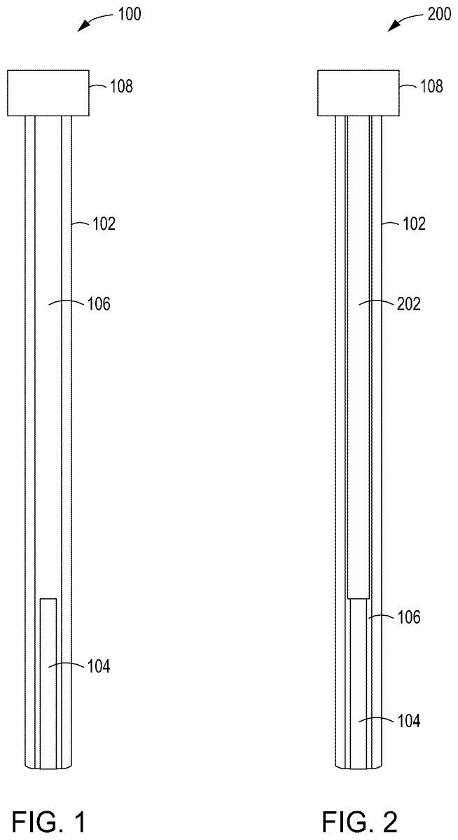

FIG. 1 depicts a schematic side view of a substrate lift pin 100 in accordance with at least some embodiments of the present disclosure. The substrate lift pin 100 includes an elongate tube 102 having a top end and a bottom end. In some embodiments, the elongate tube 102 can be formed of a ceramic material, such as for example, aluminum oxide (e.g., Al₂O₃). In some embodiments, the elongate tube 102 can be an extruded tube, such as an extruded ceramic material pressed and fired into form. The inventors have discovered when solid materials are drilled to form a tube, the center of the drilled hole can be off center (e.g., the hole can be axially offset and/or skewed with respect to the central axis), undesirably resulting in uneven stresses applied to the walls of the tube during further fabrication and during use in production, which can lead to lift pin breakage. Further, the inventors have observed that the drilling process can lead to cracks in the material in the sidewall of the tube, which further can lead to lift pin breakage. The inventors have observed that forming the elongate tube 102 as an extruded tube advantageously provides at least one of a more centered central opening and/or sidewalls with fewer or no cracks.

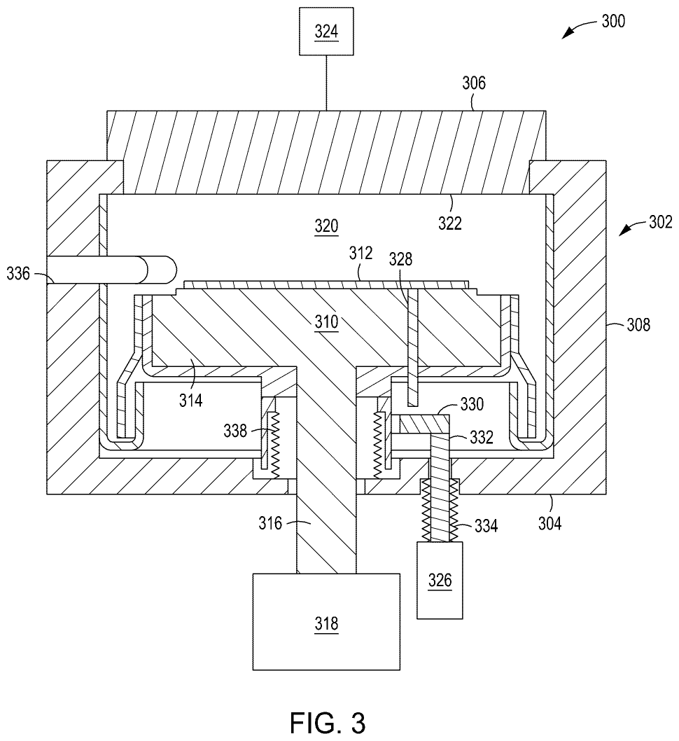

A magnetic insert 104 is disposed within the elongate tube proximate the bottom end of the elongate tube 102. The magnetic insert 104 can be fabricated of any process compatible magnetic material, such as for example, Invar®, nickel-plated steel, martensitic stainless steel, or the like. In operation, the magnetic insert 104 operates to temporarily couple the substrate lift pin 100 to a substrate lift pin positional control element, such as the second lift mechanism 326 described below with respect to FIG. 3.

The magnetic insert 104 is generally a cylinder or rod, although other cross-sectional shapes are possible, having a diameter or cross-sectional dimension smaller than the inner diameter of the elongate tube 102 (e.g., to leave a small gap, for example about 0.05-0.5 mm, such as about 0.1 mm, between the magnetic insert 104 and the inner sidewall of the elongate tube 102). Providing a gap between the magnetic insert 104 and the elongate tube 102 advantageously facilitates inserting the magnetic insert 104 into the elongate tube 102 with reduced risk of breakage of the elongate tube 102. In addition, the gap between the magnetic insert 104 and the elongate tube 102 advantageously facilitates retention of the magnetic insert 104 within the elongate tube 102 when the gap is filled with a potting material, as discussed below.

The magnetic insert 104 can generally be any length no greater than the length of the elongate tube 102. In some embodiments, the magnetic insert 104 has a length no greater than one half, or in some embodiments one quarter, of the length of the elongate tube 102. Providing a smaller length of the magnetic insert 104 advantageously reduces cost of the substrate lift pin 100 and further prevents any undesired interaction with processes being performed on the substrate.

A potting material 106 is disposed within the elongate tube 102 and secures the magnetic insert 104 within the elongate tube 102 (e.g., from above and/or from the sides by filling the gaps disposed between the magnetic insert 104 and the elongate tube 102). The inventors have observed that merely press fitting a magnetic insert into an elongate tube sometimes results in slippage of the magnetic insert partially or completely from the elongate tube. The potting material 106 advantageously enhances the retention of the magnetic insert 104 within the elongate tube 102. In some embodiments, the potting material 106 substantially fills the entire interior region of the elongate tube 102, except for space occupied by the magnetic insert 104. The magnetic insert 104 can be completely embedded within the elongate tube 102 by the potting material 106 or a bottom surface of the magnetic insert 104 can be exposed at the bottom of the elongate tube 102.

The potting material can be any process compatible potting materials that acts as a filler and as a bonding agent to bond the magnetic insert 104 to the elongate tube 102. In some embodiments, the potting material 106 can be a ceramic potting material, for example, such as an aluminum oxide-based potting material, a zirconium oxide-based potting material, or the like. Examples of suitable potting materials include Durapot™ 801 and RESBOND™ 908, commercially available from Cotronics Corp. of Brooklyn, NY.

In some embodiments, and as depicted in FIG. 2, a substrate lift pin 200, which is otherwise identical to the substrate lift pin 100, can include a rod 202 disposed within the elongate tube 102, above the magnetic insert 104. The rod 202 is generally a cylindrical rod, although other cross-sectional shapes are possible. The rod 202 has a diameter or cross-sectional dimension smaller than the inner diameter of the elongate tube 102 (e.g., to leave a small gap between the rod 202 and the inner sidewall of the elongate tube 102). The rod 202 can generally be any length no greater than the length of the elongate tube 102 not occupied by the magnetic insert 104 (e.g., the magnetic insert 104 and the rod 202 together are the same length as the elongate tube 102 or shorter than the elongate tube 102). In some embodiments, the magnetic insert 104 and the rod 202 together have a length that is the same as the length of the elongate tube 102. The rod 202 can be formed of any of the materials described above with respect to the elongate tube 102. The rod 202 is generally held in place within the elongate tube 102 by the potting material 106. In some embodiments, the potting material 106 substantially fills the entire interior region of the elongate tube, except for space occupied by the magnetic insert 104 and the rod 202.

Providing the rod 202 within the interior of the elongate tube 102 advantageously reduces the volume of potting material 106 needed to fill the interior of the elongate tube 102, thus mitigating any potential shrinkage issues with the potting material 106. In addition, securing the rod 202 to the elongate tube 102 strengthens the substrate lift pin 100 and reduces or prevents propagation of any fractures that may develop in the elongate tube 102, thus improving the useful life of the substrate lift pin 100.

A cap 108 having a support surface configured to support a substrate can be disposed on the top end of the elongate tube 102. The cap 108 generally includes a first surface, opposite the elongate tube 102, configured to support a substrate during use. In some embodiments, the cap 108 is bonded to the elongate tube 102. The cap 108 can be formed of any of the materials described above with respect to the elongate tube 102.

FIG. 3 depicts a schematic cross-sectional side view of a process chamber having a substrate support and substrate lift pins in accordance with at least some embodiments of the present disclosure. The process chamber 300 can be configured to perform processes on substrates, such as semiconductor wafers or the like. Suitable processes include etching, deposition, treating, metrology, or the like. In some embodiments, the process chamber 300 may generally be a vacuum chamber that is suitably adapted to maintain sub-atmospheric pressures within an interior volume 320 during substrate processing. The process chamber 300 includes a chamber body 302 having a bottom plate 304, a lid 306, and sidewalls 308 extending from the bottom plate 304 to the lid 306. The chamber body 302 is made of a suitable material, for example, aluminum. The process chamber 300 may also include one or more shields circumscribing various chamber components to prevent unwanted reaction between such components and ionized process material. The chamber body 302 may be grounded via a coupling to ground.

In some embodiments, a showerhead 322 is disposed in the interior volume 320 proximate the lid 306 and opposite a substrate support 310 for supporting a substrate 312. The showerhead 322 is coupled to and in fluid communication with a process gas supply 324 which may supply one or more process gases into an interior volume 320 for processing the substrate 312. The interior volume 320 may include a processing volume located in the upper half of the interior volume 320 and generally between the substrate support 310 and the showerhead 322.

The substrate support 310 is disposed within the interior volume 320 to support and retain the substrate 312, such as a semiconductor wafer, for example, or other such substrate as may be retained. The substrate support 310 may generally comprise a pedestal 314 coupled to a hollow shaft 316. The substrate support 310 may be configured in various ways to support and retain the substrate 312, such as, for example, by including an electrostatic chuck. Additional components, such as an edge ring can be disposed on the substrate support 310.

The hollow shaft 316 provides a conduit to provide, for example, backside gases, process gases, fluids, coolants, power, or the like, to the pedestal 314. In some embodiments, the hollow shaft 316 is coupled to a lift mechanism 318, such as an actuator or motor, which provides vertical movement of the pedestal 314 between an upper, processing position and a lower, transfer position. A bellows assembly 338 is disposed about the hollow shaft 316 and is coupled between the pedestal 314 and a bottom surface of the process chamber 300 to provide a flexible seal that allows vertical motion of the pedestal 314 while preventing loss of vacuum from within the process chamber 300.

In some embodiments, the hollow shaft 316 facilitates coupling a backside gas supply, a chucking power supply, and RF power sources (e.g., RF plasma power supply and a bias power supply) to the pedestal 314. The backside gas supply 141 is disposed outside of the chamber body 302 and supplies heat transfer gas to the pedestal 314. In some embodiments, a RF plasma power supply 170 and a bias power supply 117 are coupled to the pedestal 314 via respective RF match networks. In some embodiments, the substrate support 310 may alternatively include AC, DC, or RF bias power. In some embodiments, the AC, DC, or RF bias power may be pulsed.

A plurality of substrate lift pins 328 (e.g., substrate lift pins 100 or 200, described above) are provided to lower and raise the substrate 312, as needed, onto or off of the pedestal 314. The plurality of substrate lift pins 328 extend through the substrate support 310. A platform 330 connected to a shaft 332 which is coupled to a second lift mechanism 326 for raising and lowering the platform 330, and by contact, the plurality of substrate lift pins 328. The platform 330 can include a plurality of magnets in locations corresponding to the position of the plurality of substrate lift pins 328. The magnets attract the substrate lift pins 328 (e.g., via the magnetic insert 104 discussed above) to facilitate uniform positioning of the plurality of substrate lift pins 328 by control of the position of the platform 330 via the second lift mechanism 326. A bellows assembly 334 is coupled between the second lift mechanism 326 and bottom plate 304 to provide a flexible seal which maintains the chamber vacuum during vertical motion provided by the second lift mechanism 326. In some embodiments, as shown in FIG. 3, the second lift mechanism 326 is disposed outside of the hollow shaft 316.

The process chamber 300 is coupled to and in fluid communication with a vacuum system (e.g., including a throttle valve and vacuum pump, not shown) which are used to exhaust the process chamber 300. The pressure inside the process chamber 300 may be regulated by adjusting the throttle valve and/or vacuum pump. The process chamber 300 includes a slit valve 336 having a substrate transfer opening that is selectively opened or closed to facilitate transferring the substrate 312 into and out of the interior volume 320. In some embodiments, a transfer robot (not shown) having one or more transfer blades is configured to transfer the substrate 312.

While the foregoing is directed to embodiments of the present disclosure, other and further embodiments of the disclosure may be devised without departing from the basic scope thereof.

1. A substrate lift pin, comprising:
an elongate tube having a top end and a bottom end;
a magnetic insert disposed in the elongate tube proximate the bottom end; and
a potting material disposed within the elongate tube and securing the magnetic insert within the elongate tube.

2. The substrate lift pin of claim 1, further comprising a cap disposed on the top end of the elongate tube, wherein the cap includes a support surface configured to support a substrate thereon.

3. The substrate lift pin of claim 1, further comprising a rod disposed within the elongate tube, above the magnetic insert.

4. The substrate lift pin of claim 3, wherein the rod is made of a ceramic material.

5. The substrate lift pin of claim 1, wherein the elongate tube is made of a ceramic material.

6. The substrate lift pin of claim 1, wherein the elongate tube is made of aluminum oxide.

7. The substrate lift pin of claim 1, wherein the elongate tube is an extruded tube.

8. The substrate lift pin of claim 1, wherein the potting material is a ceramic-based potting material.

9. The substrate lift pin of claim 1, further comprising a cap disposed on the top end of the elongate tube, wherein the cap includes a support surface configured to support a substrate thereon, wherein the elongate tube and the cap are both made of a ceramic material, and wherein the potting material is a ceramic-based potting material.

10. The substrate lift pin of claim 9, further comprising a rod disposed within the elongate tube, above the magnetic insert.

11. A substrate support, comprising:
a support plate having an upper surface and a plurality of through holes extending through the support plate; and
a plurality of substrate lift pins each movably disposed in corresponding ones of the plurality of through holes, wherein each substrate lift pin comprises:
an elongate tube having a top end and a bottom end;
a magnetic insert disposed in the elongate tube proximate the bottom end; and
a potting material disposed within the elongate tube and securing the magnetic insert within the elongate tube.

12. The substrate support of claim 11, further comprising a cap disposed on the top end of the elongate tube, wherein the cap includes a support surface configured to support a substrate thereon.

13. The substrate support of claim 11, further comprising a rod disposed within the elongate tube, above the magnetic insert.

14. The substrate support of claim 13, wherein the rod is made of a ceramic material.

15. The substrate support of claim 11, wherein at least one of:
the elongate tube is made of a ceramic material; or
the elongate tube is an extruded tube.

16. The substrate support of claim 11, wherein the potting material is a ceramic-based potting material.

17. The substrate support of claim 11, further comprising a cap disposed on the top end of the elongate tube, wherein the cap includes a support surface configured to support a substrate thereon, wherein the elongate tube and the cap are both made of a ceramic material, and wherein the potting material is a ceramic-based potting material.

18. The substrate support of claim 17, further comprising a rod disposed within the elongate tube, above the magnetic insert.

19. A process chamber, comprising:
a chamber body defining an interior volume therein;
a substrate support disposed in the interior volume, the substrate support comprising a support plate having an upper surface and a plurality of through holes extending through the support plate; and
a plurality of substrate lift pins each movably disposed in corresponding ones of the plurality of through holes, wherein each substrate lift pin comprises:
an elongate tube having a top end and a bottom end;
a magnetic insert disposed in the elongate tube proximate the bottom end; and
a potting material disposed within the elongate tube and securing the magnetic insert within the elongate tube.

20. The process chamber of claim 19, further comprising a cap disposed on the top end of the elongate tube, wherein the cap includes a support surface configured to support a substrate thereon, wherein the elongate tube and the cap are both made of a ceramic material, and wherein the potting material is a ceramic-based potting material.
